(19) United States
(12) Patent Application Publication
(10) Pub. No.: US 2014/0239419 A1
(43) Pub. Date: Aug. 28, 2014

(54) SEMICONDUCTOR DEVICE AND METHOD OF MANUFACTURING THE SAME

(71) Applicant: UNITED MICROELECTRONICS CORP., Hsinchu (TW)

(72) Inventors: Chien-Hao Chen, Yunlin County (TW); Hsin-Fu Huang, Tainan City (TW); Chi-Yuan Sun, Yunlin County (TW); Min-Chuan Tsai, New Taipei City (TW); Wei-Yu Chen, Tainan City (TW); Nien-Ting Ho, Tainan City (TW); Tsun-Min Cheng, Changhua County (TW); Chi-Mao Hsu, Tainan City (TW)

(73) Assignee: UNITED MICROELECTRONICS CORP., HSINCHU (TW)

(21) Appl. No.: 13/778,227

(22) Filed: Feb. 27, 2013

(51) Int. Cl. H01L 29/423; H01L 29/40

(52) U.S. Cl. CPC H01L 29/42364; H01L 29/401
USPC 257/411; 438/591

(57) ABSTRACT

A method of manufacturing a semiconductor device is provided. A silicon substrate is provided, and a gate insulating layer is formed on the silicon substrate. Then, a silicon barrier layer is formed on the gate insulating layer by the physical vapor deposition (PVD) process. Next, a silicon-containing layer is formed on the silicon barrier layer. The silicon barrier layer of the embodiment is a hydrogen-substantial-zero silicon layer, which has a hydrogen concentration of zero substantially.

### BACKGROUND

1. Technical Field

The disclosure relates in general to a semiconductor device and a method of manufacturing the same, and more particularly to the semiconductor device and method of manufacturing the same for reducing the PBTI (positive bias temperature instability) defect.

2. Description of the Related Art

Size of semiconductor device has been decreased for these years. Reduction of feature size, improvements of the rate, the efficiency, the density and the cost per integrated circuit unit are the important goals in the semiconductor technology. The electrical properties (such as junction leakage) of the device have to be maintained even improved with the decrease of the size, to meet the requirements of the commercial products in applications. A high-K dielectric film is one of the important features in the semiconductor manufacturing of memory applications. Take a current high K-metal gate process for example, an amorphous silicon, as a dummy gate in the high-K first high K-metal gate process, is deposited at a low temperature of about 500□. Typically, the amorphous silicon is deposited by a chemical vapor deposition (CVD) process using the precursor of silane (SiH4). However, low temperature process for amorphous Si deposition would cause too much hydrogen, and those hydrogen may penetrate to the silicon substrate. Combination of H and SiH of the silicon substrate would cause the undesired defects of the silicon substrate, thereby inducing PBTI (positive bias temperature instability) degradation and degrading the stability of the device.

### SUMMARY

The disclosure is directed to a semiconductor device and method of manufacturing the same, which are provided to reduce PBTI (positive bias temperature instability) defect, so as to improve the electrical properties and stability of the semiconductor device.

According to the disclosure, a method for manufacturing a semiconductor device is provided. A silicon substrate is provided, and a gate insulating layer is formed on the silicon substrate. Then, a silicon barrier layer is formed on the gate insulating layer by the physical vapor deposition (PVD) process. Next, a silicon-containing layer is formed on the silicon barrier layer.

According to the disclosure, a semiconductor device is provided, comprising a silicon substrate, a gate insulating layer formed on the silicon substrate, a silicon barrier layer formed on the gate insulating layer, and a silicon-containing layer formed on the silicon barrier layer, wherein a hydrogen concentration of the silicon barrier layer is substantial zero.

According to the disclosure, another semiconductor device is provided, comprising a silicon substrate, a gate insulating layer formed on the silicon substrate, and a silicon-containing layer formed on the gate insulating layer, wherein a hydrogen concentration of the silicon-containing layer exhibits a concentration distribution from extremely low to high corresponding to a direction from the nearest to the farthest to the gate insulating layer.

### BRIEF DESCRIPTION OF THE DRAWINGS

FIG. 1 illustrates a semiconductor device according to the embodiment of the present disclosure.

FIG. 2A illustrates a semiconductor device having a dummy gate according to the first embodiment of the present disclosure applied to a high K-metal gate process.

FIG. 2B-FIG. 2D illustrate a subsequent process for manufacturing the semiconductor device with metal gate according to the first embodiment of the present disclosure applied to a high K-metal gate process.

FIG. 3A illustrates a semiconductor device having a dummy gate according to the second embodiment of the present disclosure applied to a high K-metal gate process.

FIG. 3B-FIG. 3F illustrate a subsequent process for manufacturing the semiconductor device with metal gate according to the second embodiment of the present disclosure applied to a high K-metal gate process.

FIG. 4A illustrates a semiconductor device having a gate-pattern stack according to the third embodiment of the present disclosure applied to a poly-gate process.

FIG. 4B illustrates a semiconductor device having a poly-gate according to the third embodiment of the present disclosure applied to a poly-gate process.

### DETAILED DESCRIPTION

In the present disclosure, a semiconductor device and method of manufacturing the same are provided to reduce PBTI (positive bias temperature instability) defect, thereby improving stability of the semiconductor device. According to the embodiments, a silicon barrier layer is deposited by PVD (physical vapor deposition) before the deposition of a silicon gate, for stopping the hydrogen of the silicon gate from penetrating into the silicon substrate.

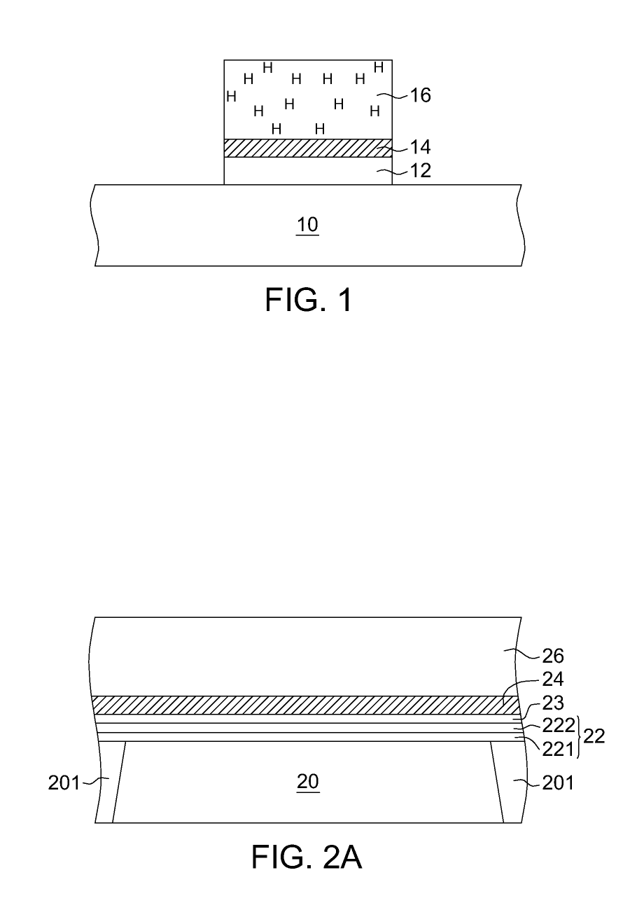

FIG. 1 illustrates a semiconductor device according to the embodiment of the present disclosure. According to a method of manufacturing the semiconductor device of the embodiment, a gate insulating layer 12 is formed on a silicon substrate 10, and a silicon barrier layer 14 is formed on the gate insulating layer 12 by the physical vapor deposition (PVD) process. Next, a silicon-containing layer 16 is formed on the silicon barrier layer 14. The silicon-containing layer 16 could be an amorphous silicon layer as a dummy gate in the application of high K-metal gate process, or a polysilicon layer as a poly-gate in the application of poly-gate process. Also, the gate insulating layer 12 could be a single insulating layer or multi-layer insulation in the practical applications. Also, the semiconductor device in the practical application may include other elements, and is not limited to the illustrations of the embodiments.

In one embodiment, the silicon-containing layer 16 is formed by a chemical vapor deposition (CVD) process. The CVD process could be, but not limitedly, performed at a temperature of about or above 500□. Also, silane (SiH4) could be the precursor for conducting the CVD process to form the silicon-containing layer 16.

In one embodiment, a solid pure silicon target could be adopted for performing the PVD process to form the silicon barrier layer 14. Crystal form of the silicon barrier layer 14 could be amorphous silicon. In one embodiment, both of the silicon-containing layer 16 and the silicon barrier layer 14 could be amorphous silicon. However, the disclosure does not limit the crystalline morphology of the layers, and the silicon barrier layer 14 could be formed as other crystalline types.

The silicon barrier layer 14 of the embodiments contains extremely low concentration of hydrogen. In one embodiment, the hydrogen concentration of the silicon barrier layer 14 is substantial zero. Accordingly, the silicon barrier layer 14 of the embodiment could be regarded as a hydrogen-substantial-zero layer, which substantially has a hydrogen concentration of zero. The hydrogen concentration of the silicon barrier layer 14 is much less than that of the silicon-containing layer 16.

In one embodiment, the silicon barrier layer 14 has a thickness ranged from 30 Å to 400 Å. In another embodiment, the silicon barrier layer 14 has a thickness ranged from 40 Å to 200 Å. However, the disclosure does not limit the thickness of the silicon barrier layer 14, as long as it is sufficiently capable of stopping the penetration of the hydrogen of the silicon-containing layer 16 to the silicon substrate 10.

Although the silicon barrier layer 14 formed by the PVD process would be hydrogen-free, the silicon-containing layer 16 formed by the CVD process subsequently would contain considerable amounts of hydrogen. It is highly likely that small amounts of hydrogen of the silicon-containing layer 16 diffuse into the silicon barrier layer 14. Thus, the silicon barrier layer 14 of the semiconductor device manufactured by the method of the embodiment would contain extremely low hydrogen concentration.

According to the semiconductor device of the embodiment, the less hydrogen concentration is corresponding to a portion of the silicon-containing layer 16 closer to the silicon barrier layer 14, while the higher hydrogen concentration is corresponding to another portion of the silicon-containing layer 16 farther to the silicon barrier layer 14. Also, if both of the silicon-containing layer 16 and the silicon barrier layer 14 are amorphous silicon, they could be regarded as one amorphous silicon layer formed on the gate insulating layer 12, wherein a hydrogen concentration of the silicon-containing layer 16 exhibits a concentration distribution from extremely low to high corresponding to a direction from the nearest to the farthest to the gate insulating layer 12.

The embodiments are described in details with reference to the accompanying drawings. The first and second embodiments of the disclosure are provided for describing applications of the high K-metal gate process, while the third embodiment is provided for describing application of the poly-gate process. The similar elements of the embodiments are designated with similar reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense. Moreover, the steps and elements in details of the embodiments could be modified or changed according to the actual needs of the practical applications. The disclosure is not limited to the descriptions of the embodiments.

### First Embodiment

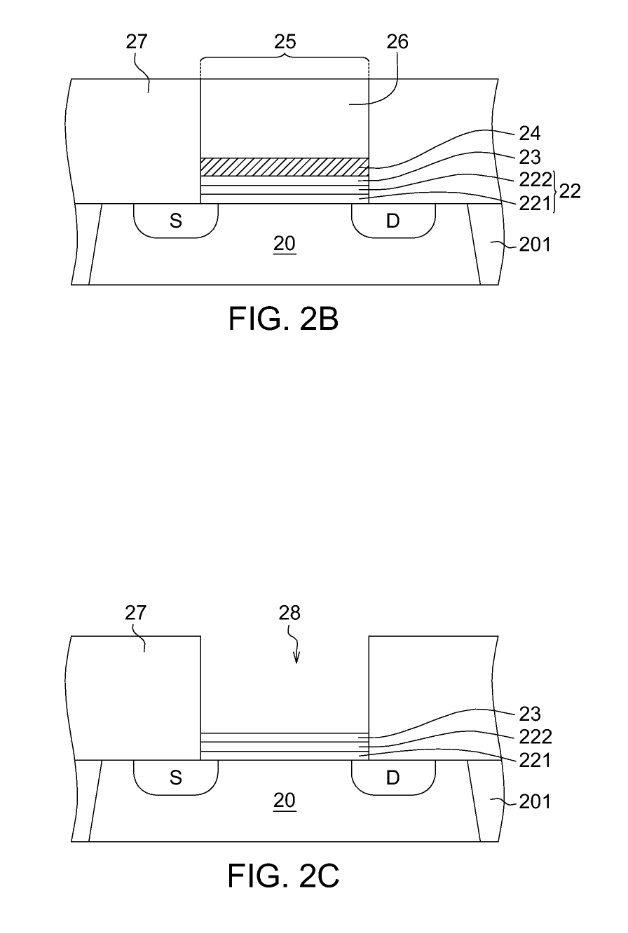

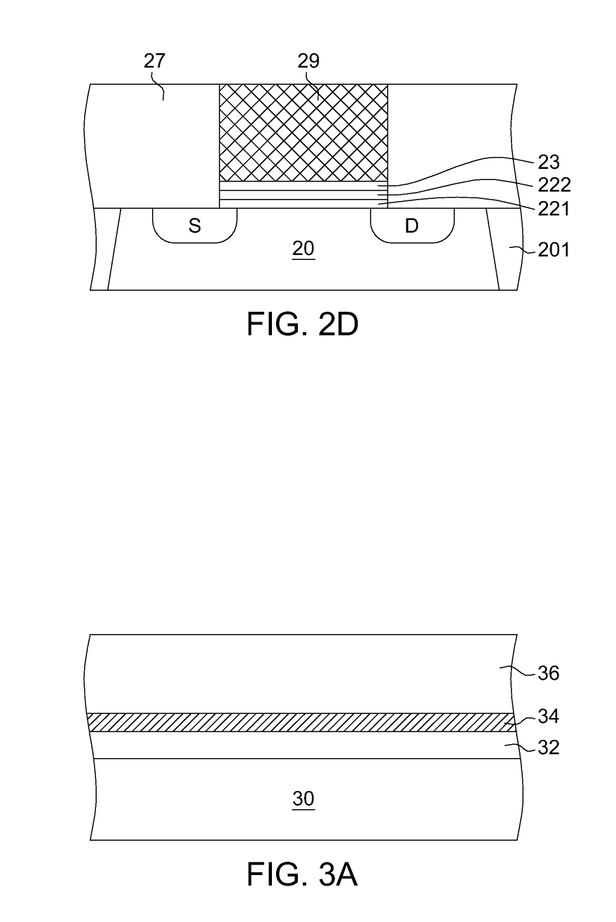

FIG. 2A illustrates a semiconductor device having a dummy gate according to the first embodiment of the present disclosure applied to a high K-metal gate process. The first embodiment discloses a semiconductor device and manufacturing method thereof related to a high-K first high K-metal gate process.

Please refer to FIG. 1 and FIG. 2A. First, a gate insulating layer 22 is formed on a silicon substrate 20. The silicon substrata 20 may include shallow trench isolations (STIs). In the first embodiment, the multi-layer insulation is exemplified as the gate insulating layer 22, and the fabricating steps comprise forming an interfacial layer (IL) 221 on the silicon substrate 20, and forming a high K dielectric layer 222 on the interfacial layer 221. The interfacial layer 221 isolates the high K dielectric layer 222 from the silicon substrate 20.

Material examples of the interfacial layer 221 include, but are not limited to, oxides. Material examples of the high-k gate dielectric layer 222 include, but are not limited to, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate and other suitable materials.

In the first embodiment, a bottom barrier metal (BBM) 23 is further formed on the high K dielectric layer 222, functioning as a buffering layer for the high K dielectric layer 222 and the amorphous silicon layer (formed later). Material examples of the bottom barrier metal (BBM) 23 include, but are not limited to, TiN and other suitable materials.

Then, a silicon barrier layer 24 is formed on the bottom barrier metal 23l by PVD. Next, an amorphous silicon layer 26, as a dummy poly-gate layer in the high K-metal gate process, is formed on the silicon barrier layer 24.

In one embodiment, the silicon barrier layer 24 has a thickness of about 40 Å. In another embodiment, the silicon barrier layer 24 has a thickness ranged from 30 Å to 400 Å. In another embodiment, the silicon barrier layer 24 has a thickness ranged from 40 Å to 200 Å. In one embodiment, the hydrogen concentration of the silicon barrier layer 24 is extremely low and close to zero.

FIG. 2B-FIG. 2D illustrate a subsequent process for manufacturing the semiconductor device with metal gate according to the first embodiment of the present disclosure applied to a high K-metal gate process. As shown in FIG. 2B, the stacking layers (26, 24 and 22) of FIG. 2A are patterned to form a gate-pattern stack 25, followed by implanting source S and drain D. An interlayer dielectric (ILD) 27 is deposited and then planarized (ex: by chemical mechanical polishing (CMP) and/or etching). As shown in FIG. 2C, the amorphous silicon layer 26 and the silicon barrier layer 24 of the gate-pattern stack 25 are removed (by etching, for example) to form a trench 28. As shown in FIG. 2D, a metal gate 29 is formed in the trench 28, to complete the replacement of dummy amorphous silicon gate with metal gate. Materials of the metal gate 29 could be, but are not limited to, the work function metals suitable for adjusting the work functions of N/P-type transistors, and the metals with low resistance. Examples of the work function metals include TiN, TaN, titanium carbide (TiC), tantalum carbide (TaC), tungsten carbide (WC), or aluminum titanium nitride (TiAlN) ′titanium aluminide (TiAl), zirconium aluminide (ZrAl), tungsten aluminide (WAl), tantalum aluminide (TaAl), or hafnium aluminide (HfAl). Examples of the metals with low resistance include Al, Cu and other suitable materials. The work function metal could be in form of a U-shaped film conformal to the trench 28, and the remaining space of the trench 28 could be filled with the metal with low resistance.

According to descriptions above, the interfacial layer 221, the high-k gate dielectric layer 222 and the bottom barrier metal 23 are formed before formation of the silicon barrier layer 24. However, the disclosure is not limited to those descriptions, and the elements and configurations of the embodiment could be selectively modified or changed according to the actual needs of practical application; for example, the bottom barrier metal 23 and the interfacial layer 221 could be optionally formed or not formed in the semiconductor device.

### Second Embodiment

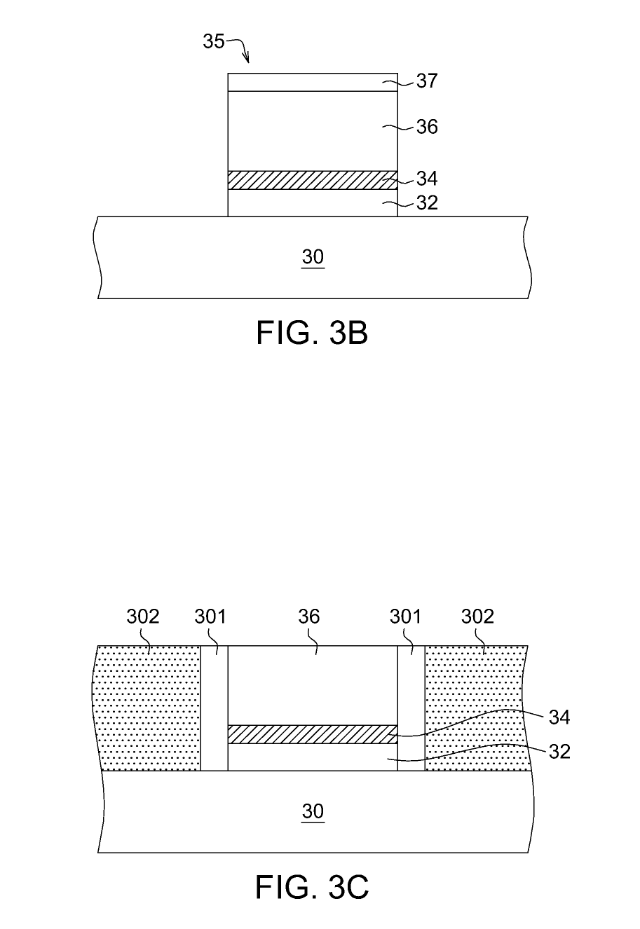

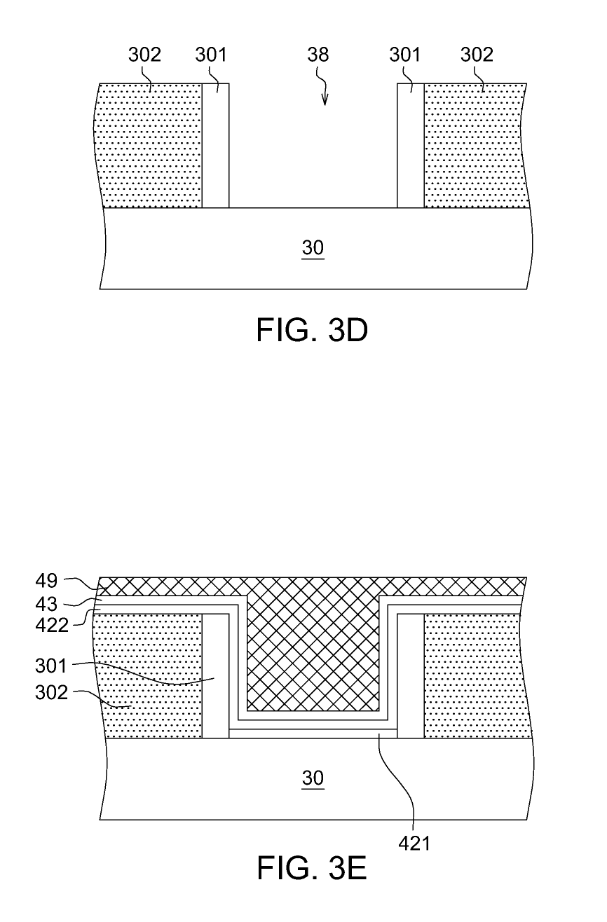

FIG. 3A illustrates a semiconductor device having a dummy gate according to the second embodiment of the present disclosure applied to a high K-metal gate process. The second embodiment discloses a semiconductor device and manufacturing method thereof related to a high-K last high K-metal gate process.

As shown in FIG. 3A, a gate insulating layer 32 is formed on a silicon substrata 30. In the second embodiment, a single layer is exemplified as the gate insulating layer 32, formed of an oxide layer or the likes. Then, a silicon barrier layer 34 is formed on the gate insulating layer 32 by PVD. An amorphous silicon layer 36 is formed on the silicon barrier layer 34. The silicon barrier layer 34 deposited by PVD stops the penetration of hydrogen of the amorphous silicon layer 36 to the silicon substrata 30, thereby preventing the surface defects on the silicon substrate.

In one embodiment, the silicon barrier layer 34 has a thickness of about 40 Å. In another embodiment, the silicon barrier layer 34 has a thickness ranged from 30 Å to 400 Å. In another embodiment, the silicon barrier layer 34 has a thickness ranged from 40 Å to 200 Å. In one embodiment, the hydrogen concentration of the silicon barrier layer 34 is extremely low and close to zero.

FIG. 3B-FIG. 3F illustrate a subsequent process for manufacturing the semiconductor device with metal gate according to the second embodiment of the present disclosure applied to a high K-metal gate process. A hard mask layer (not shown) may further be formed on the stacking layers of FIG. 3A, and patterned by dry etching or wet etching. As shown in FIG. 3B, the stacking layers (36, 34 and 32) of FIG. 3A are patterned by the patterned hard mask layer 37 to form a gate-pattern stack 35. The amorphous silicon layer 36 and the silicon barrier layer 34 of the gate-pattern stack 35 function as a dummy amorphous silicon gate layer in the high K-metal gate process.

After formation of the gate-pattern stack 35, the device may further undergo additional CMOS process, and various features could be formed according to the device requirement of the practical applications. In the second embodiment, features of the spacers 301 and the ILD 302 are taken for illustration. The spacers 301 are formed adjacent to the gate-pattern stack 35, and the ILD 302 is deposited to fill the gaps between the gate-pattern stacks 35. Afterward, the ILD 302 is planarized by CMP and/or etching until the surface of the amorphous silicon layer 36 is exposed, as shown in FIG. 3C. Then, the amorphous silicon layer 36 and the silicon barrier layer 34, and optionally the gate insulating layer 32, of the gate-pattern stack 35 are removed (by etching, for example) to form a trench 38, as shown in FIG. 3D.

Next, an interfacial layer 421 is formed on the silicon substrate 30 within the trench 38 (the gate insulating layer 32 being removed in FIG. 3D), and a high-K dielectric layer 422 is formed on the interfacial layer 421, and a bottom barrier metal (BBM) 43 is formed on the high-K dielectric layer 422, as shown in FIG. 3E. The high-K dielectric layer 422 is deposited on the top surfaces of the spacers 301 and the ILD 302, on the sidewalls of the trench 38 and on the interfacial layer 421. The interfacial layer 421 isolates the high K dielectric layer 422 from the silicon substrate 30. Material examples of the interfacial layer 421, the high K dielectric layer 422 and the bottom barrier metal (BBM) 43 are listed in the first embodiment, and not redundantly described herein.

Then, a metal layer 49 is formed to fill the trench 38, and planarized, such as by CMP, to form a metal gate 49′ in the trench 38 to complete the replacement of dummy poly-gate with metal gate, as shown in FIG. 3F. In the embodiment, materials of the metal layer 49/metal gate 49′ could be, but are not limited to, the work function metals suitable for adjusting the work functions of N/P-type transistors, and the metals with low resistance. Examples of the work function metals include TiN, TaN, titanium carbide (TiC), tantalum carbide (TaC), tungsten carbide (WC), or aluminum titanium nitride (TiAlN) ′titanium aluminide (TiAl), zirconium aluminide (ZrAl), tungsten aluminide (WAl), tantalum aluminide (TaAl), or hafnium aluminide (HfAl). Examples of the metals with low resistance include Al, Cu and other suitable materials.

The procedures in the second embodiment are related to a high-K last high K-metal gate process since the high K dielectric layer 422 is deposited after formation of the trench 38. Also, the high K dielectric layer 422 and the bottom barrier metal (BBM) 43 could be in form of a conformal U-shaped cross-sections as shown in FIG. 3F, and the remaining space of the trench 38 could be filled with the metal with low resistance to form the metal gate 49′.

It is noted that the manufacturing steps and the feature configurations could be modified and changed according to the actual needs of the practical applications. For example, after forming the interfacial layer 421, the high-K dielectric layer 422 and the BBM 43, a capping layer could be deposited thereon and an annealing process is performed such as by a rapid thermal process (RTP) (of about 700˜1000□) to repair the defects on the interfaces between the interfacial layer 421, the high-K dielectric layer 422 and the BBM 43. It is known that the disclosure could be applied to the applications with steps not described herein.

### Third Embodiment

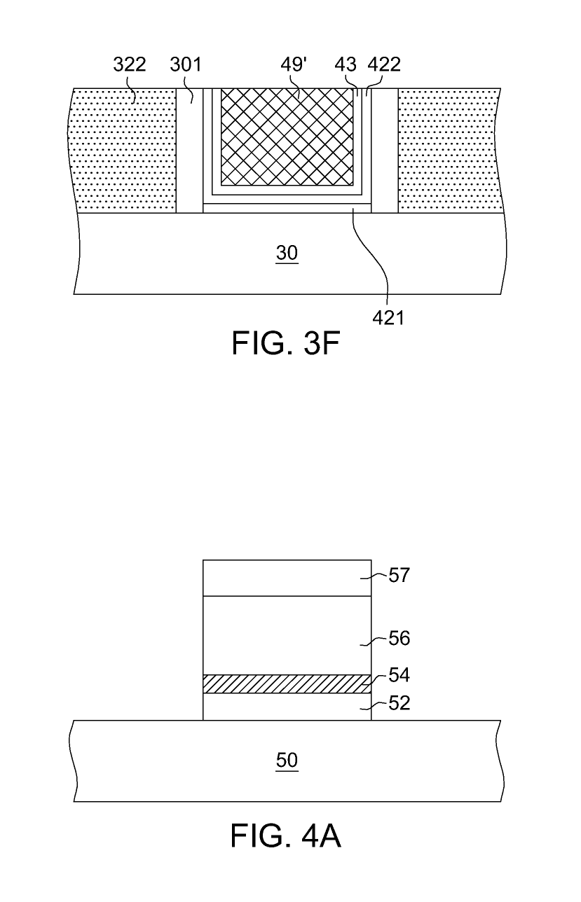

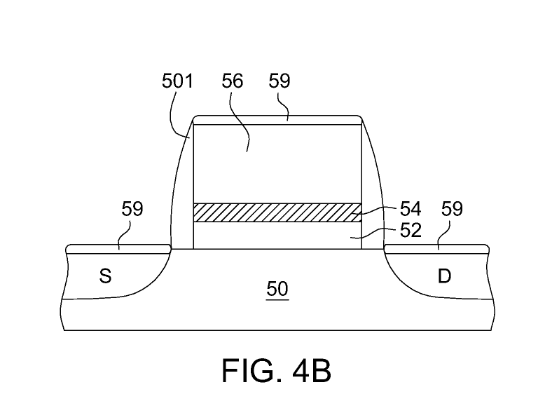

FIG. 4A illustrates a semiconductor device having a gate-pattern stack according to the third embodiment of the present disclosure applied to a poly-gate process. As shown in FIG. 4A, the semiconductor device having a gate-pattern stack comprises a silicon substrata 50, a gate insulating layer 52 (such as a SiON layer or the likes) formed on the silicon substrata 50, a silicon barrier layer 54 formed on the gate insulating layer 52 by PVD, and a polysilicon layer 56 formed on the silicon barrier layer 54. In the third embodiment, a single layer is exemplified as the gate insulating layer 52, but the disclosure is not limited thereto. Also, a patterned hard mask layer 37 is further formed on the polysilicon layer 56. The silicon barrier layer 54 deposited by PVD stops the penetration of hydrogen of the polysilicon layer 56 to the silicon substrata 50, thereby preventing the surface defects on the silicon substrate.

In one embodiment, the silicon barrier layer 54 has a thickness of about 40 Å. In another embodiment, the silicon barrier layer 54 has a thickness ranged from 30 Å to 400 Å. In another embodiment, the silicon barrier layer 54 has a thickness ranged from 40 Å to 200 Å. In one embodiment, the hydrogen concentration of the silicon barrier layer 54 is extremely low and close to zero.

FIG. 4B illustrates a semiconductor device having a poly-gate according to the third embodiment of the present disclosure applied to a poly-gate process. The subsequent process for manufacturing the semiconductor device with poly-gate according to the third embodiment may include implanting source S and drain D, forming a salicide 59 on the polysilicon layer 56 and S/D, and forming the spacers 501 etc., to complete the fabrication of the semiconductor device with poly-gate. As shown in FIG. 4B, the polysilicon layer 56 and the salicide 59 above function as a poly-gate of the semiconductor device of the third embodiment.

Accordingly to the aforementioned descriptions, a silicon barrier layer is deposited by PVD before deposition of the silicon-containing layer (e.g. the amorphous silicon layers 26 and 36 of the metal-gate process, and the polysilicon layer 56 of the poly-gate process). The PVD silicon barrier layer contains extremely low concentration of the hydrogen (of substantial zero), and is capable to stop the hydrogen from penetrating into the silicon substrate, thereby reducing the PBTI (positive bias temperature instability) degradation on the silicon substrate. Also, the disclosure does not limit the thickness of the silicon barrier layer in the applications, as long as it sufficiently stops the penetration of the hydrogen from the silicon-containing layer to the silicon substrate. Also, the thickness of the silicon-containing layer could be varied and adjusted, depending on the thickness of the silicon barrier layer and the actual needs of the practical application. Besides the embodiments provided above, other embodiments with different configurations of features, such as gate, source drain and/or ILD are also applicable, which could be varied depending on the actual needs of the applications. It is, of course, noted that the configurations of embodiments are depicted only for demonstration, not for limitation. It is known by people skilled in the art that the shapes or positional relationship of the constituting elements could be adjusted according to the requirements and/or manufacturing methods of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for manufacturing semiconductor device, comprising:
providing a silicon substrate;
forming a gate insulating layer on the silicon substrate;
forming a silicon barrier layer on the gate insulating layer by PVD, wherein the silicon barrier layer is an amorphous silicon layer; and
forming a silicon-containing layer on the silicon barrier layer.

2. The method according to claim 1, wherein the silicon barrier layer has a thickness ranged from 30 Å to 400 Å.

3. The method according to claim 1, wherein the silicon-containing layer is formed by CVD.

4. The method according to claim 1, wherein the silicon-containing layer and the silicon barrier layer are amorphous silicon.

5. The method according to claim 1, wherein step of forming the gate insulating layer comprises:
forming an interfacial layer on the silicon substrate, and
forming a high K dielectric layer on the interfacial layer.

6. The method according to claim 5, further comprising forming a bottom barrier metal (BBM) on the high K dielectric layer, and the silicon barrier layer is formed on the bottom barrier metal by PVD.

7. The method according to claim 1, wherein the gate insulating layer comprises an interfacial layer, and the silicon barrier layer is formed on the interfacial layer by PVD.

8. The method according to claim 1, further comprising removing the silicon-containing layer and the silicon barrier layer to form a trench.

9. The method according to claim 8, further comprising forming a metal gate in the trench.

10. The method according to claim 8, further comprising:
forming a high K dielectric layer in the trench; and
forming a metal gate on the high K dielectric layer in the trench.

11. The method according to claim 1, wherein the gate insulating layer comprises a SiON layer, and the silicon barrier layer is formed on the SiON layer by PVD.

12. A semiconductor device, comprising:
a silicon substrate;
a gate insulating layer formed on the silicon substrate;
a silicon barrier layer formed on the gate insulating layer, wherein the silicon barrier layer is an amorphous silicon layer, and a hydrogen concentration of the silicon barrier layer is substantial zero; and
a silicon-containing layer formed on the silicon barrier layer.

13. The device according to claim 12, wherein in the silicon-containing layer, the less hydrogen concentration is corresponding to a portion of the silicon-containing layer closer to the silicon barrier layer, while the higher hydrogen concentration is corresponding to another portion of the silicon-containing layer farther to the silicon barrier layer.

14. The device according to claim 12, wherein the silicon barrier layer has a thickness ranged from 30 Å to 400 Å.

15. The device according to claim 12, wherein the gate insulating layer comprises:
an interfacial layer formed on the silicon substrate, and
a high K dielectric layer formed on the interfacial layer.

16. The device according to claim 15, further comprising a bottom barrier metal (BBM) formed on the high K dielectric layer, wherein the silicon barrier layer is formed on the BBM.

17. The device according to claim 12, wherein the gate insulating layer comprises an interfacial layer, and the silicon barrier layer is formed on the interfacial layer.

18. The device according to claim 12, wherein the gate insulating layer comprises a SiON layer, and the silicon barrier layer is formed on the SiON layer.

19. A semiconductor device, comprising:
a silicon substrate;
a gate insulating layer formed on the silicon substrate;
a silicon-containing layer formed on the gate insulating layer, and a hydrogen concentration of the silicon-containing layer exhibiting a concentration distribution from extremely low to high corresponding to a direction from the nearest to the farthest to the gate insulating layer, wherein the silicon-containing layer is an amorphous silicon layer.

20. The device according to claim 19, wherein a portion adjacent to the gate insulating layer is a hydrogen-substantial zero layer with a thickness of 30 Å to 400 Å.
